(19) United States
(12) Patent Application Publication
(10) Pub. No.: US 2006/0285303 A1
(43) Pub. Date: Dec. 21, 2006

(54) HOUSING OF A MEMORY CARD CAPABLE OF CONTAINING A PLURALITY OF MEMORY CHIPS

(76) Inventor: Min-Chou Chuang, Chia-Yi Hsien (TW)

Correspondence Address: NORTH AMERICA INTELLECTUAL PROPERTY CORPORATION, P.O. BOX 506, MERRIFIELD, VA, 22116, US

(21) Appl. No.: 11/163,056

(22) Filed: Oct. 3, 2005

Related U.S. Application Data
(60) Provisional application No. 60/595,205, filed on Jun. 15, 2005.

(51) Int. Cl. H05K 5/00

(52) U.S. Cl. 361/752; 361/737

(57) ABSTRACT

A housing of a memory card includes an upper cover and a lower cover. An angle between a largest inner plane of the upper cover and a largest outer plane of the upper cover is between 0.3 and 1 degrees. An angle between a largest inner plane of the lower cover and a largest outer plane of the lower cover is between 0.3 and 1 degrees. Therefore, the lower cover is capable of being united with the upper cover for containing a plurality of memory chips.

### CROSS REFERENCE TO RELATED APPLICATIONS

The application claims the benefit of U.S. Provisional Application No. 60/595,205, filed Jun. 15, 2005, and included herein by reference.

### BACKGROUND OF THE INVENTION

1. Field of the Invention

The present invention relates to a housing of a memory card, and more particularly, to a housing of a memory card capable of containing a plurality of memory chips.

2. Description of the Prior Art

As related technology keeps improving, portable electronic devices such as digital cameras, personal digital assistants (PDA), and MP3 players etc. become more and more popular. Therefore, various types of memory cards are developed for data storage. Presently, the most common memory cards are Compact Flash (CF) cards, Secure Digital (SD) cards, Multimedia cards (MMC), and the recently unveiled MiniSD and RSMMC (All Trademarks of their respective owners).

Please refer to FIG. 1 and FIG. 2. FIG. 1 is an exploded view of a Secure Digital card 100 of the prior art, FIG. 2 shows the Secure Digital card 100 of FIG. 1 from another view angle. The Secure Digital card 100 comprises an upper cover 110, a lower cover 120, and a printed circuit board 130. The printed circuit board 130 comprises a memory chip 132 (flash memory chip), and a plurality of contact pad surfaces 134 electrically connected to the memory chip 132. The upper cover 110 comprises a plurality of openings 112 corresponding to the plurality of contact pad surfaces 134, such that the contact pad surfaces 134 are capable of electrically connecting the memory chip 132 to an electronic device (such as a digital camera) for accessing data. The Secure Digital card 100 further comprises a controller unit 233 fixed on the printed circuit board 130 for controlling data accessing between the electronic device and the memory chip 132.

Please refer to FIG. 3, and refer to FIG. 1 and FIG. 2 as well. FIG. 3 is a lateral exploded view of the Secure Digital card 100 shown in FIG. 1. In the prior art, a largest inner plane 114 of the upper cover 110 is parallel to a largest outer plane 116 of the upper cover 110, and a largest inner plane 124 of the lower cover 120 is parallel to a largest outer plane 126 of the lower cover 120. Therefore, the lower cover 120 is capable of being united with the upper cover 110 for flatly accommodating the printed circuit board 130 in between.

Any memory chip has its standard packaging size. As shown in FIG. 4, if adding one more memory chip 136 on the printed circuit 140 in order to increase memory capacity and data transmission speed of the Secure Digital card 100, the edge 137 of the memory chip 136 will be over the edge 113 of the openings 112. This is because the dimensions of the Secure Digital card 100 must meet a standard specification. As shown in FIG. 5, the standard thickness, which is from the top of the contact pad surface 134 to the bottom of the lower cover 120, is between 1.30 mm and 1.60 mm. Hence, if the edge 137 of the memory chip 136 is over the edge 113 of the openings 112, the printed circuit board 140 will interfere with the housing (that is the upper cover 110 and the lower cover 120) of the Secure Digital card 100, and cause the thickness, which is from the top of the contact pad surface 134 to the bottom of the lower cover 120, to deviate from the specification. Therefore, the housing of the Secure Digital card 100 of the prior art cannot contain a plurality of memory chips.

### SUMMARY OF THE INVENTION

It is therefore an objective of the claimed invention to provide a housing of a memory card capable of containing a plurality of memory chips in order to solve the problems of the prior art.

The present invention provides a housing of a memory card that includes an upper cover and a lower cover. An angle between a largest inner plane of the upper cover and a largest outer plane of the upper cover is between 0.3 and 1 degrees; an angle between a largest inner plane of the lower cover and a largest outer plane of the lower cover is between 0.3 and 1 degrees. Therefore, the lower cover is capable of being united with the upper cover for containing a plurality of memory chips.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an exploded view of a Secure Digital card of the prior art.

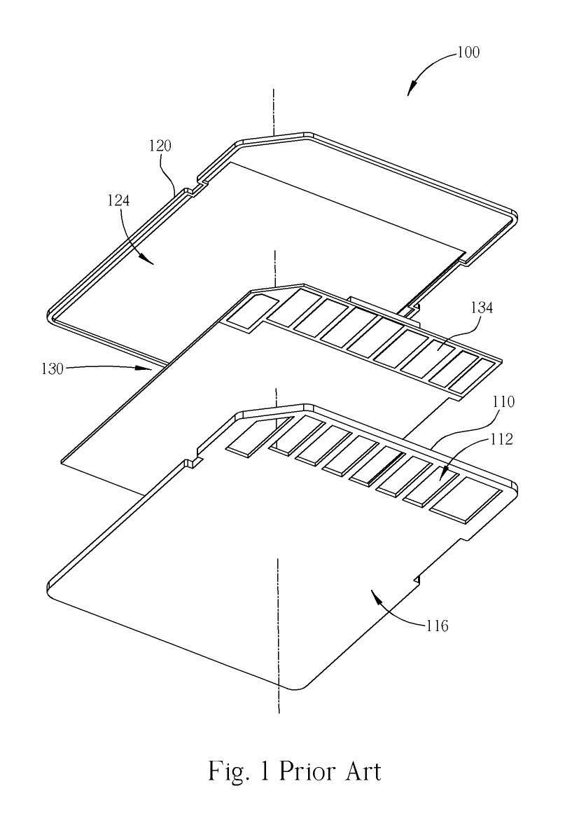

FIG. 2 is a diagram showing the Secure Digital card of FIG. 1 from another view angle.

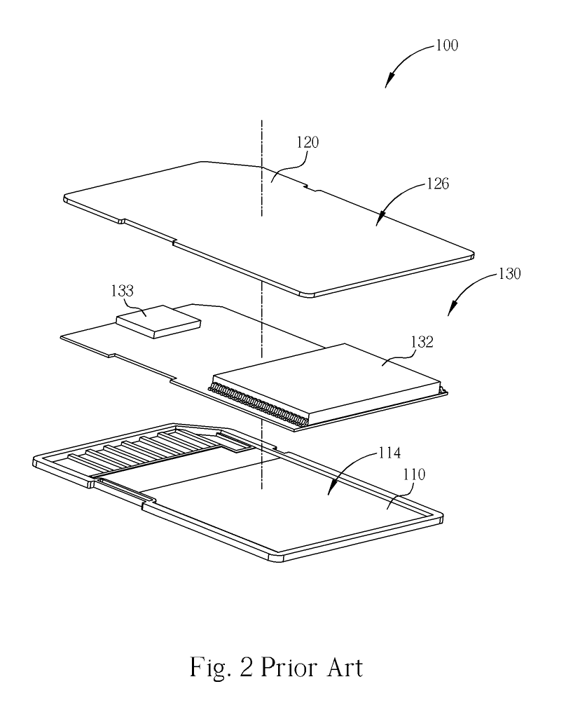

FIG. 3 is a lateral exploded view of the Secure Digital card shown in FIG. 1.

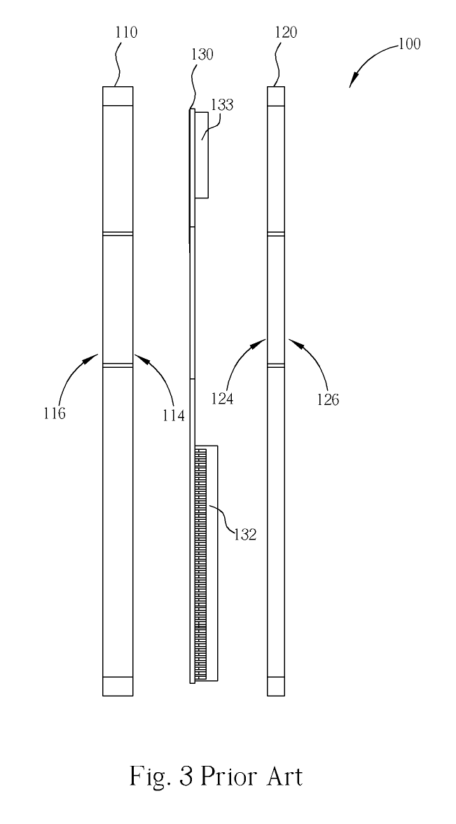

FIG. 4 is a diagram showing the Secure Digital card of FIG. 1 having one additional memory chip on the printed circuit board.

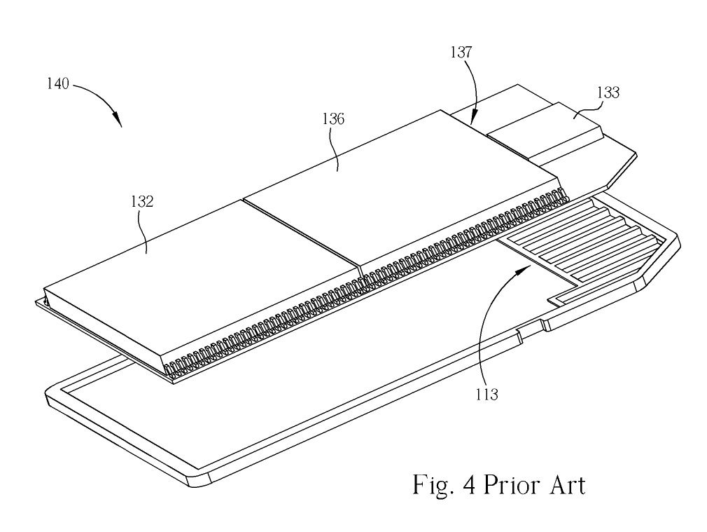

FIG. 5 is a diagram showing a standard dimension of a Secure Digital card of the prior art.

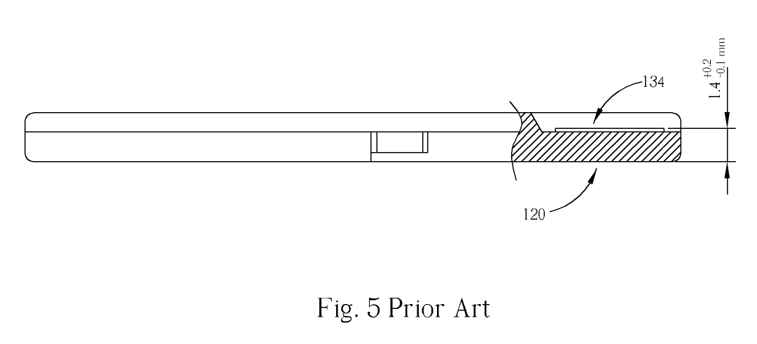

FIG. 6 is an exploded view of a Secure Digital card of the present invention.

FIG. 7 is a diagram showing the Secure Digital card of FIG. 6 from another view angle.

FIG. 8 is a lateral exploded view of the Secure Digital card shown in FIG. 6.

FIG. 9 is a cross-sectional view of the housing of the Secure Digital card shown in FIG. 6.

### DETAILED DESCRIPTION

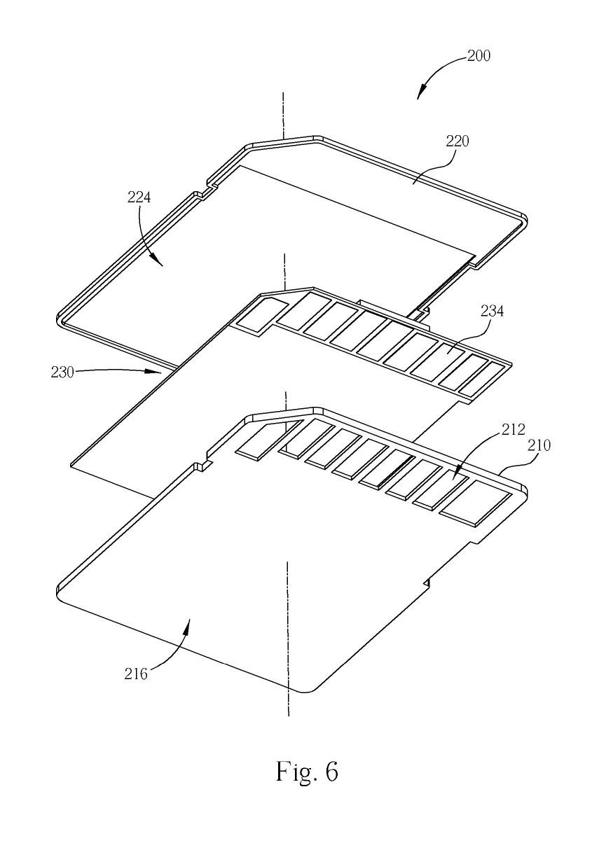

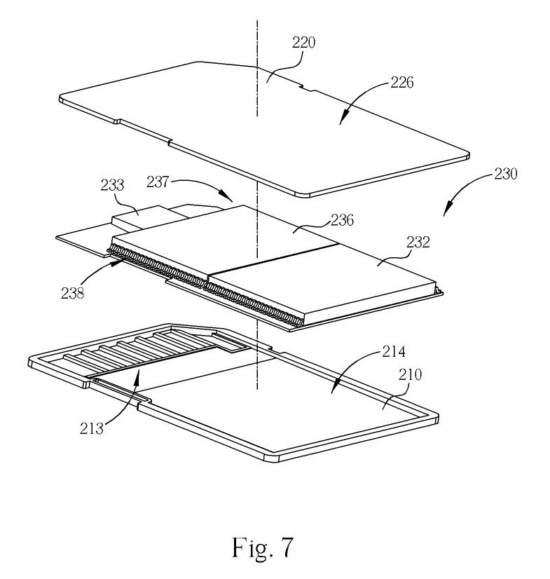

Please refer to FIG. 6 and FIG. 7. FIG. 6 is an exploded view of a Secure Digital card 200 of the present invention, FIG. 7 shows the Secure Digital card 200 of FIG. 6 from another view angle. The Secure Digital card 200 of the present invention comprises an upper cover 210, a lower cover 220, and a printed circuit board 230. The printed circuit board 230 comprises two memory chips 232, 236, and a plurality of contact pad surfaces 234 electrically connected to the memory chips 232, 236. The upper cover 210 comprises a plurality of openings 212 corresponding to the plurality of contact pad surfaces 234, such that the contact pad surfaces 234 are capable of electrically connecting the memory chips 232, 236 to an electronic device for accessing data. The Secure Digital card 200 further comprises a controller unit 233 fixed on the printed circuit board 230 for controlling data accessing between the electronic device and the memory chip 232, 236.

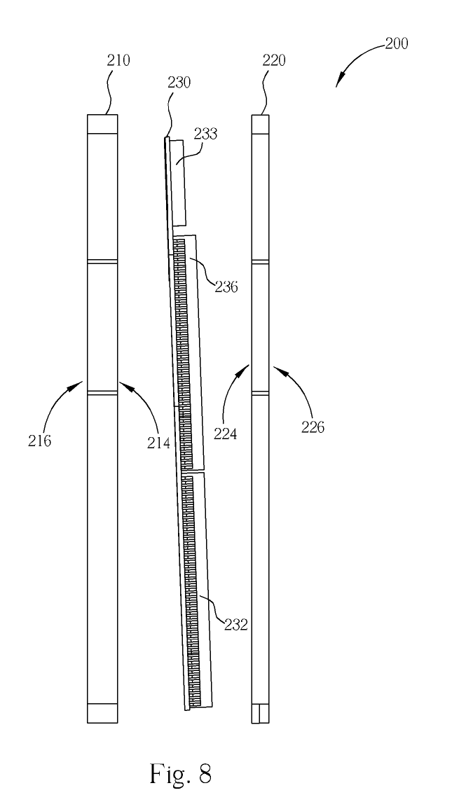

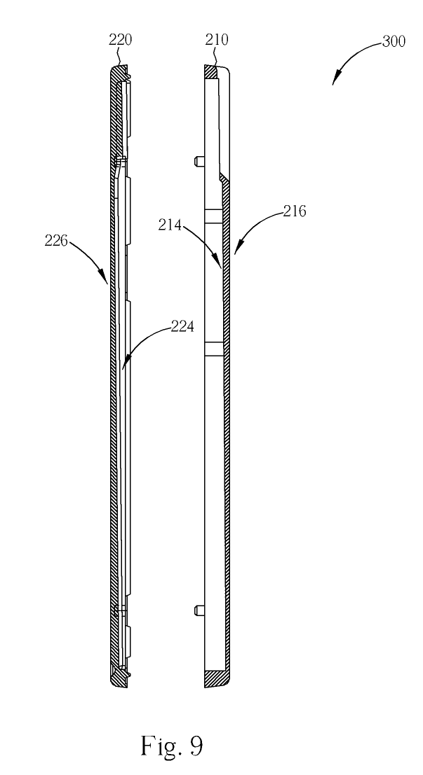

Please refer to FIG. 8 and FIG. 9, and refer to FIG. 6 and FIG. 7 as well. FIG. 8 is a lateral exploded view of the Secure Digital card 200 shown in FIG. 6, and FIG. 9 is a cross-sectional view of a housing 300 of the Secure Digital card 200 shown in FIG. 6. Different from the Secure Digital card 100 of the prior art, the angle between a largest inner plane 214 of the upper cover 210 and a largest outer plane 216 of the upper cover 210 is between 0.3 and 1 degrees, accordingly, the angle between a largest inner plane 224 of the lower cover 220 and a largest outer plane 226 of the lower cover 220 is also between 0.3 and 1 degrees. The angle of the upper cover 210 is corresponding to the angle of the lower cover 220, and therefore, the lower cover 220 is capable of being united with the upper cover 210 for obliquely accommodating the printed circuit board 230 in between.

Because the printed circuit board 230 is obliquely accommodated between the upper cover 210 and the lower cover 220 thereby increasing the space between the upper cover 210 and the lower cover 220, especially in the thickness dimension, an edge 237 of the memory chip 236 will not be over an edge 213 of the openings 212. In other words, the thickness, which is from the top of the contact pad surface 234 to the bottom of the lower cover 220, does not deviate from that allowed by specification. For example, if the angle of the upper cover 210 and the angle of the lower cover 220 both are 0.67 degrees, based on the result of measurement, the edge 237 of the memory chip 236 is not over the edge 213 of the openings 212, and the thickness, which is from the top of the contact pad surface 234 to the bottom of the lower cover 220, is about 1.58 mm, which is in the range of the specification (1.30 mm˜1.60 mm). From the above, the housing 300 (that is the upper cover 210 and the lower cover 220) of the Secure Digital card of the present invention is capable of containing a plurality of memory chips.

In addition, one or more pin(s) 238 of the memory chip 236 closest to the plurality of contact pad surfaces 234 is usually a null pin. Therefore, in the present invention, the pin(s) closest to the plurality of contact pad surfaces 234 is not connected to the printed circuit board 230 in order to decrease the thickness of the printed circuit board 230 at the side near the contact pad surfaces 234, and thus increase tolerance in the thickness dimension. In the above preferred embodiment, both the upper cover 210 and the lower cover 220 have an angle between the largest inner and outer planes. However, in other preferred embodiments of the present invention, one cover can have an angle between the largest inner and outer planes with the other cover's largest inner and outer planes parallel to each other, as long as one cover has an angle between the largest inner and outer planes for increasing space inside the housing in the thickness dimension. For example, the upper cover 210 has an angle between the largest inner and outer planes 214, 216, and the lower cover's 220 largest inner and outer planes 224, 226 are parallel to each other. Or, the lower cover 220 has an angle between the largest inner and outer planes 224, 226, and the upper cover's 210 largest inner and outer planes 214, 216 are parallel to each other.

Summarizing the above, the present invention changes the interior structure of the housing 300 of the Secure Digital card 200 for increasing space between the upper cover 210 and the lower cover, especially in the thickness dimension. Therefore, the housing 300 of the Secure Digital card 200 is capable of containing a plurality of memory chips 232, 236 without causing the edge 237 of the memory chip 236 to interfere with the edge 213 of the openings 212. This means that the thickness from the top of the contact pad surface 234 to the bottom of the lower cover 220 will be within the specification (1.30 mm˜1.60 mm).

In contrast to the prior art, the present invention is capable of containing a plurality of memory chips while still meeting the dimensions of Secure Digital cards as set forth in the related specification. Therefore, the Secure Digital card 200 of the present invention possesses higher memory capacity and data transmission speed compared to the prior art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A housing of a memory card capable of containing a plurality of memory chips, comprising:
an upper cover, wherein an angle between a largest inner plane of the upper cover and a largest outer plane of the upper cover is between 0.3 and 1 degrees; and
a lower cover, wherein an angle between a largest inner plane of the lower cover and a largest outer plane of the lower cover is between 0.3 and 1 degrees, the lower cover capable of being united with the upper cover for containing a plurality of memory chips.

2. The housing of claim 1 wherein the upper cover comprises a plurality of openings.

3. The housing of claim 1 being a housing of a Secure Digital (SD) memory card.

4. A memory card capable of containing a plurality of memory chips, comprising:
an upper cover, wherein an angle between a largest inner plane of the upper cover and a largest outer plane of the upper cover is between 0.3 and 1 degrees;
a lower cover, wherein an angle between a largest inner plane of the lower cover and a largest outer plane of the lower cover is between 0.3 and 1 degrees; and
a printed circuit board accommodated between the upper cover and the lower cover, the printed circuit board comprising:
a first memory chip fixed on the printed circuit board;
a second memory chip fixed on the printed circuit board; and
a plurality of contact pad surfaces electrically connected to the first memory chip and the second memory chip.

5. The memory card of claim 4 further comprising a controller unit fixed on the printed circuit board.

6. The memory card of claim 4 wherein the upper cover comprises a plurality of openings corresponding to the plurality of contact pad surfaces.

7. The memory card of claim 4 wherein a null pin of the first memory chip is not welded onto the printed circuit board.

8. The memory card of claim 7 wherein the null pin is a pin of the first memory chip closest to the plurality of contact pad surfaces.

9. The memory card of claim 4 wherein the plurality of contact pad surfaces are for electrically connecting an electronic device to the first memory chip and the second memory chip for accessing data.

10. The memory card of claim 4 being a Secure Digital (SD) memory card.

11. A housing of a memory card capable of containing a plurality of memory chips, comprising:
an upper cover, wherein an angle between a largest inner plane of the upper cover and a largest outer plane of the upper cover is equal to a specific angle greater than 0 degrees; and
a lower cover, wherein an angle between a largest inner plane of the lower cover and a largest outer plane of the lower cover is equal to the specific angle, the lower cover capable of being united with the upper cover for containing a plurality of memory chips.

12. The housing of claim 10 wherein the upper cover comprises a plurality of openings.

13. The housing of claim 10 being a housing of a Secure Digital (SD) memory card.

14. A memory card capable of containing a plurality of memory chips, comprising:
an upper cover, wherein an angle between a largest inner plane of the upper cover and a largest outer plane of the upper cover is equal to a specific angle greater than 0 degrees;
a lower cover, wherein an angle between a largest inner plane of the lower cover and a largest outer plane of the lower cover is equal to the specific angle; and
a printed circuit board accommodated between the upper cover and the lower cover, the printed circuit board comprising:
a first memory chip fixed on the printed circuit board;
a second memory chip fixed on the printed circuit board; and
a plurality of contact pad surfaces electrically connected to the first memory chip and the second memory chip.

15. The memory card of claim 14 further comprising a controller unit fixed on the printed circuit board.

16. The memory card of claim 14 wherein the upper cover comprises a plurality of openings corresponding to the plurality of contact pad surfaces.

17. The memory card of claim 14 wherein a null pin of the first memory chip is not welded onto the printed circuit board.

18. The memory card of claim 17 wherein the null pin is a pin of the first memory chip closest to the plurality of contact pad surfaces.

19. The memory card of claim 14 wherein the plurality of contact pad surfaces are for electrically connecting an electronic device to the first memory chip and the second memory chip for accessing data.

20. The memory card of claim 14 being a Secure Digital (SD) memory card.

21. A housing of a memory card capable of containing a plurality of memory chips, comprising:
a first cover, wherein an angle between a largest inner plane of the first cover and a largest outer plane of the first cover is between 0.3 and 1 degrees; and
a second cover capable of being united with the first cover for containing a plurality of memory chips.

22. The housing of claim 19 wherein the first cover comprises a plurality of openings.

23. The housing of claim 19 wherein the second cover comprises a plurality of openings.

24. The housing of claim 19 being a housing of a Secure Digital (SD) memory card.
